(19) United States
(12) Patent Application Publication
(10) Pub. No.: US 2026/0295760 A1
(43) Pub. Date: Oct. 1, 2026

(54) GRINDING WHEEL, METHOD FOR GRINDING WORKPIECE, AND METHOD FOR MANUFACTURING CHIP

(71) Applicant: DISCO CORPORATION, Tokyo (JP)

(72) Inventors: Koji Shiono, Tokyo (JP); Daisuke Akita, Tokyo (JP)

(21) Appl. No.: 19/544,119

(22) Filed: Feb. 19, 2026

(30) Foreign Application Priority Data
Mar. 28, 2025 (JP) 2025-056174

(51) Int. Cl. B24B 27/06; H10P 58/00

(52) U.S. Cl. CPC B24B 27/0675; H10P 58/00

(57) ABSTRACT

A grinding wheel 1 is for grinding a back surface side of a plate-shaped workpiece having a front surface and a back surface on the side opposite to the front surface, and includes a wheel base 10 having a first surface 11 and a second surface 12 on the side opposite to the first surface 11, the first surface 11 side being mounted on a spindle rotating in a predetermined rotation direction, grinding abrasive products 20 disposed on the second surface 12 side of the wheel base 10 and having a bottom surface 21 in contact with the back surface of the workpiece, and a movement controller 30 that movably controls the grinding abrasive product 20 such that the contact area of the bottom surface 21 is changed in terms of the bottom surface 21 of the grinding abrasive product 20 with respect to the back surface of the workpiece.

### CROSS-REFERENCE TO RELATED APPLICATION(S)

The present application claims priority to and incorporates by reference the entire contents of Japanese Patent Application No. 2025-056174 filed in Japan on Mar. 28, 2025.

### BACKGROUND

The present disclosure relates to a grinding wheel for grinding a plate-shaped workpiece, a method for grinding a workpiece, and a method for manufacturing a chip.

When a device chip including an optical device such as a light emitting diode (LED) is manufactured, a hard substrate such as a sapphire substrate or a SiC substrate having excellent mechanical and thermal characteristics and chemical stability is generally used.

After a light emitting layer or the like serving as an optical device is formed on a surface of such a hard substrate, a back surface of the hard substrate is ground by a grinding device for weight reduction, size reduction, and the like of an electric device (see, for example, JP 2017-47520 A).

The grinding device disclosed in JP 2017-47520 A includes at least a chuck table that has a holding surface for holding a workpiece and is rotatable, a grinding unit such as a spindle that rotatably supports a grinding wheel on which an abrasive product member for grinding the workpiece held on the chuck table is annularly arranged, and a grinding feed unit that causes the grinding unit to approach and move away from the chuck table, and can grind a plate-shaped workpiece to a desired thickness.

However, the grinding device disclosed in JP 2017-47520 A has a problem that high Mohs hardness of a hard substrate prevents the abrasive product member containing diamond abrasives as a main component from penetrating a back surface of the hard substrate, and thus grinding does not proceed, and grinding load due to a grinding feed is excessively increased, causing damage to the hard substrate.

Therefore, there is a problem that a grinding wheel that grinds a workpiece needs to be provided in which a grinding load on the workpiece does not excessively increase.

### SUMMARY

A grinding wheel according to one aspect of the present disclosure is used when grinding a back surface side of a plate-shaped workpiece having a front surface and a back surface on the side opposite to the front surface, and includes: a wheel base having a first surface and a second surface on the side opposite to the first surface, the first surface side being mounted on a spindle rotating in a predetermined rotation direction; a plurality of abrasive product members disposed on the second surface side of the wheel base and having a bottom surface in contact with the back surface of the workpiece; and a movement controller configured to movably control the abrasive product member such that the contact area of the bottom surface is changed in terms of the bottom surface of the abrasive product member with respect to the back surface of the workpiece.

A grinding method of a workpiece according to another aspect of the present disclosure grinds the workpiece using the above-described grinding wheel, and includes: holding the front surface side of the workpiece with a chuck table; and grinding the workpiece by bringing the bottom surface of the abrasive product member into contact with the back surface of the workpiece while supplying liquid to the back surface side of the workpiece. The grinding includes, by the grinding wheel, grinding by controlling the bottom surface of the abrasive product member such that the contact area of the bottom surface is changed with respect to the back surface of the workpiece.

A method according to still another aspect of the present disclosure is for manufacturing a chip by dividing a workpiece into individual chips using the above-described grinding wheel, and includes: holding the front surface side of the workpiece with a chuck table, and grinding the workpiece to thin the workpiece by bringing the bottom surface of the abrasive product member into contact with the back surface of the workpiece while supplying liquid to the back surface side of the workpiece; and dividing the workpiece into individual chips or forming a division starting point on the workpiece to process the workpiece. The grinding to thin the workpiece includes, by the grinding wheel, grinding by controlling the bottom surface of the abrasive product member such that the contact area of the bottom surface is changed with respect to the back surface of the workpiece.

### BRIEF DESCRIPTION OF THE DRAWINGS

FIG. 1 is a perspective view illustrating a configuration example of a grinding device to which a grinding wheel according to a first embodiment is mounted;

FIG. 2 is a perspective view schematically illustrating a workpiece to be processed by the grinding device illustrated in FIG. 1;

FIG. 3 is a perspective view schematically illustrating the workpiece illustrated in FIG. 2 from a back surface side;

FIG. 4 is a plan view illustrating the grinding wheel according to the first embodiment;

FIG. 5 is a cross-sectional view taken along line V-V passing through an axial center in FIG. 4;

FIG. 6 is a flowchart illustrating a flow of a method for manufacturing a chip according to the first embodiment;

FIG. 7 is an enlarged cross-sectional view illustrating a main part of a holding step in the method for manufacturing a chip illustrated in FIG. 6;

FIG. 8 is an enlarged cross-sectional view illustrating a state in which a bottom surface of a grinding abrasive product abuts on a back surface of the workpiece in a grinding step of the method for manufacturing a chip illustrated in FIG. 6;

FIG. 9 is an enlarged cross-sectional view illustrating a state in which the grinding wheel is fed for grinding in the grinding step of the method for manufacturing a chip illustrated in FIG. 6;

FIG. 10 is an enlarged cross-sectional view illustrating the grinding abrasive product illustrated in FIG. 9;

FIG. 11 is an enlarged cross-sectional view illustrating an abrasive product member in a state in which the grinding abrasive product illustrated in FIG. 10 starts grinding the workpiece;

FIG. 12 is an enlarged cross-sectional view illustrating the abrasive product member in a state in which the grinding abrasive product illustrated in FIG. 11 is grinding the workpiece;

FIG. 13 is a side view schematically illustrating a processing step of the method for manufacturing a chip illustrated in FIG. 6 in a partial cross section;

FIG. 14 is a flowchart illustrating a flow of a method for manufacturing a chip according to a second embodiment;

FIG. 15 is a side view schematically illustrating a processing step of the method for manufacturing a chip illustrated in FIG. 14 in a partial cross section;

FIG. 16 is a plan view illustrating a grinding wheel according to a first modification;

FIG. 17 is a cross-sectional view taken along line XVII-XVII passing through an axial center in FIG. 16;

FIG. 18 is a plan view illustrating a grinding wheel according to a second modification;

FIG. 19 is a cross-sectional view taken along line XIX-XIX passing through an axial center in FIG. 18;

FIG. 20 is a plan view illustrating a grinding wheel according to a third modification;

FIG. 21 is a cross-sectional view taken along line XXI-XXI passing through an axial center in FIG. 20; and

FIG. 22 is a plan view illustrating a grinding wheel according to a comparative example.

### DETAILED DESCRIPTION

Modes (embodiments) for performing the present disclosure will be described in detail with reference to the drawings. The present invention is not limited by the contents described in the following embodiments. In addition, the components described below include those that can be easily assumed by those skilled in the art and those that are substantially the same. Furthermore, the configurations described below can be appropriately combined. In addition, various omissions, substitutions, or changes in the configuration can be made without departing from the gist of the present invention.

### First Embodiment

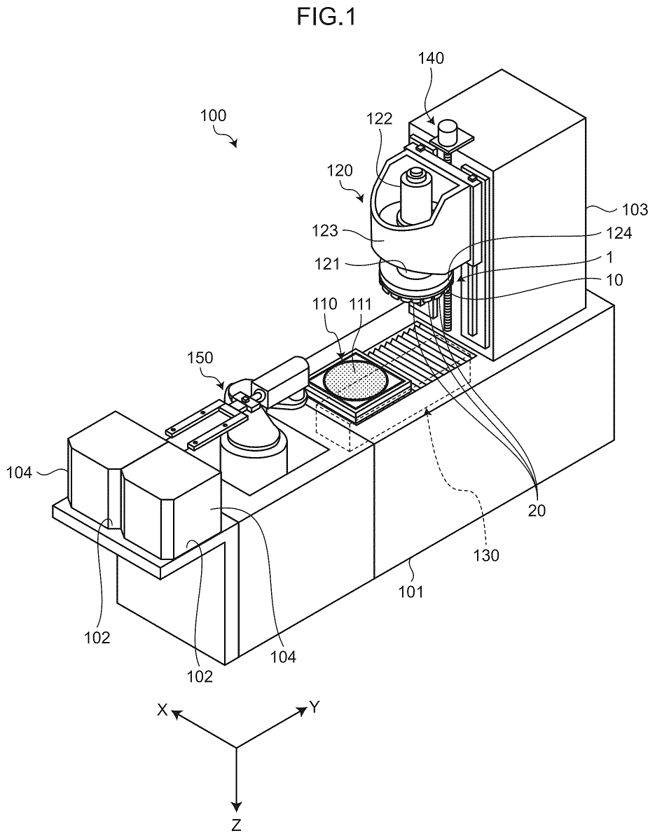

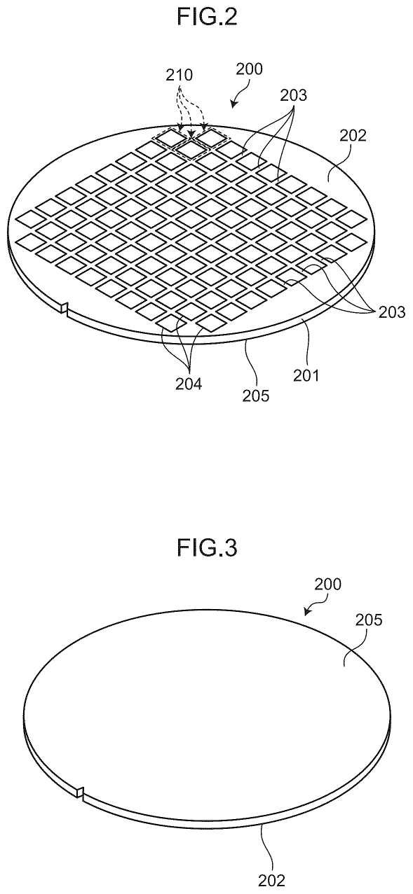

A grinding wheel according to a first embodiment of the present disclosure will be described with reference to the drawings. FIG. 1 is a perspective view illustrating a configuration example of a grinding device to which the grinding wheel according to the first embodiment is mounted. FIG. 2 is a perspective view schematically illustrating a workpiece to be processed by the grinding device illustrated in FIG. 1. FIG. 3 is a perspective view schematically illustrating the workpiece illustrated in FIG. 2 from a back surface side.

### Workpiece

A grinding wheel 1 according to the first embodiment is mounted on a grinding device 100 illustrated in FIG. 1. The grinding device 100 illustrated in FIG. 1 is a processing device that performs grinding processing (corresponding to processing) on a workpiece 200 illustrated in FIGS. 2 and 3. The workpiece 200 to be processed by the grinding device 100 illustrated in FIG. 1 is, for example, a wafer such as a disk-shaped semiconductor wafer using silicon, sapphire, gallium, SiC, or the like as a substrate 201, or an optical device wafer.

As illustrated in FIG. 2, in the workpiece 200, a device 204 is formed in each region divided in a lattice shape by a plurality of division-planned lines 203 intersecting each other on a front surface 202. The device 204 is, for example, an integrated circuit such as an integrated circuit (IC) or a large scale integration (LSI), an image sensor such as a charge coupled device (CCD) or a complementary metal oxide semiconductor (CMOS), an optical device such as a light emitting diode (LED), or a memory (semiconductor storage device).

In the first embodiment, the workpiece 200 illustrated in FIGS. 2 and 3 is an optical device wafer in which the substrate 201 is made of sapphire or SiC and the device 204 is an optical device such as a light emitting diode (LED). In the first embodiment, the substrate 201 constituting the workpiece 200 is harder than a substrate made of silicon. As described above, in the first embodiment, the workpiece 200 is made of sapphire, SiC, or the like in which the substrate 201 is a difficult-to-grind material that is harder to grind than silicon. The workpiece 200 has a circular front surface 202 and a circular back surface 205 on the side opposite to the front surface 202.

### Grinding Device

Next, the grinding device 100 illustrated in FIG. 1 will be described. The grinding device 100 is a processing device that performs grinding processing on the back surface 205 of the workpiece 200. As illustrated in FIG. 1, the grinding device 100 includes a device base 101, a chuck table 110, a grinding unit 120, a processing feed unit 130, a grinding feed unit 140, a cassette placing table 102, a loading and unloading unit 150, and a control unit (not illustrated).

The chuck table 110 holds the workpiece 200 in a state where the front surface 202 side of the workpiece 200 on which the device 204 is formed is held by a holding surface 111 and the back surface 205 of the workpiece 200 is exposed. The chuck table 110 has a disk shape, and the holding surface 111 that holds the workpiece 200 is formed of porous ceramic or the like.

In the chuck table 110, the holding surface 111 is connected to a suction source (not illustrated), and the holding surface 111 is sucked by the suction source to suck and hold the workpiece 200 placed on the holding surface 111. The chuck table 110 is rotatable about an axis parallel to a Z-axis direction by a rotary drive source (not illustrated). The Z-axis direction is a direction parallel to a vertical direction (also referred to as an up-down direction) and orthogonal to the holding surface 111. The chuck table 110 sucks and holds the workpiece 200 on the holding surface 111 and rotates about the axis by the rotary drive source, thereby supporting the workpiece 200 so as to be rotatable about the axis.

The grinding unit 120 is a processing unit that rotates the grinding wheel 1, which is a processing tool, about the axis to perform grinding processing on the workpiece 200 held on the chuck table 110. The grinding unit 120 is supported by an upright column 103 erected from one end in a Y-axis direction parallel to a horizontal direction of the device base 101 via the grinding feed unit 140.

As illustrated in FIG. 1, the grinding unit 120 includes a spindle 121 arranged to extend along the Z-axis direction, a spindle motor 122 that rotates the spindle 121 about the axis, and a spindle housing 123 that rotatably holds the spindle 121 about the axis.

The spindle 121 is formed in a columnar shape in which an axial center is arranged along the Z-axis direction, which is the vertical direction. In the spindle 121, a disk-shaped mount 124 to which the grinding wheel 1 can be mounted is disposed at a lower end, which is a distal end. That is, the grinding wheel 1 can be disposed at the lower end of the spindle 121. The spindle 121 is disposed coaxially with the mount 124.

The spindle motor 122 is mounted to an upper end (corresponding to a base end) of the spindle 121. In the first embodiment, the spindle motor 122 includes a rotor attached to the spindle 121 and a stator mounted on the spindle housing 123, and rotates the rotor, that is, the spindle 121 about the axis by applying power to a coil of the stator.

The spindle housing 123 is formed in a cylindrical shape and houses the spindle 121 except for a lower end portion of the spindle 121. The spindle housing 123 rotatably supports the spindle 121 about the axis.

The processing feed unit 130 is installed on the device base 101 and moves the chuck table 110 relative to the grinding unit 120 in the Y-axis direction, which is a processing feed direction parallel to the holding surface 111. The processing feed unit 130 moves the chuck table 110 in the Y-axis direction to move the chuck table 110 between a loading and unloading position where the workpiece 200 is loaded into and unloaded from the chuck table 110 while the chuck table is separated from the grinding unit 120 and a processing position where the workpiece 200 is ground by the grinding unit 120 while being located below the grinding unit 120. That is, the grinding unit 120 is disposed above the chuck table 110 positioned at the processing position.

The grinding feed unit 140 is a moving unit that is attached to the upright column 103 erected from one end in the Y-axis direction of the device base 101 and moves the grinding unit 120 in the Z-axis direction orthogonal to the holding surface 111. That is, the grinding feed unit 140 is a moving unit that moves the chuck table 110 and the grinding unit 120 in a direction of relatively approaching and separating. The grinding feed unit 140 lowers the spindle housing 123 of the grinding unit 120 to bring a grinding abrasive product 20 close to the workpiece 200 held on the chuck table 110 at the processing position, and raises the spindle housing 123 to move the grinding abrasive product 20 away from the workpiece 200 held on the chuck table 110 at the processing position.

The processing feed unit 130 and the grinding feed unit 140 include a known ball screw rotatably provided around the axis, a known pulse motor that rotates the ball screw around the axis, and a known guide rail that movably supports the chuck table 110 or the grinding unit 120 in an X-axis direction or the Z-axis direction.

The cassette placing table 102 is installed at the other end portion of the device base 101 in the Y axis direction, and a cassette 104 is placed thereon. The cassette 104 is a storage container having a plurality of slots and configured to accommodate a plurality of workpieces 200. The cassette 104 accommodates a plurality of workpieces 200 before and after the grinding processing. In the first embodiment, a pair of cassette placing tables 102 is provided, and the cassette 104 is installed in each cassette placing table. The cassette placing table 102 liftably supports the cassette 104 along the Z-axis direction.

The loading and unloading unit 150 is installed between the chuck table 110 at the loading and unloading position and the cassette placing table 102. The loading and unloading unit 150 takes out the workpiece 200 before the grinding processing from the cassette 104 and conveys the workpiece to the chuck table 110 at the loading and unloading position, and takes out the workpiece 200 after the grinding processing from the chuck table 110 at the loading and unloading position to load the workpiece into the cassette 104. The loading and unloading unit 150 is, for example, a robot pick including a U-shaped hand, and sucks and holds the workpiece 200 with the U-shaped hand and conveys the workpiece.

The control unit controls each of the above-described components constituting the grinding device 100. That is, the control unit causes the grinding device 100 to execute a processing operation on the workpiece 200. The control unit is a computer that includes an arithmetic processing device including a microprocessor such as a central processing unit (CPU), a storage device including a memory such as a read only memory (ROM) or a random access memory (RAM), and an input and output interface device, and is capable of executing a computer program.

The arithmetic processing device of the control unit executes a computer program stored in the ROM on the RAM to generate a control signal for controlling the grinding device 100. The arithmetic processing device of the control unit outputs the generated control signal to each component of the grinding device 100 via the input and output interface device. In addition, the control unit is connected to a display unit (not illustrated) including a liquid crystal display device or the like that displays a state of a processing operation, an image, and the like, and an input unit used when an operator registers processing conditions. The input unit includes at least one of a touch panel provided on the display unit, a keyboard, and the like.

### Grinding Wheel

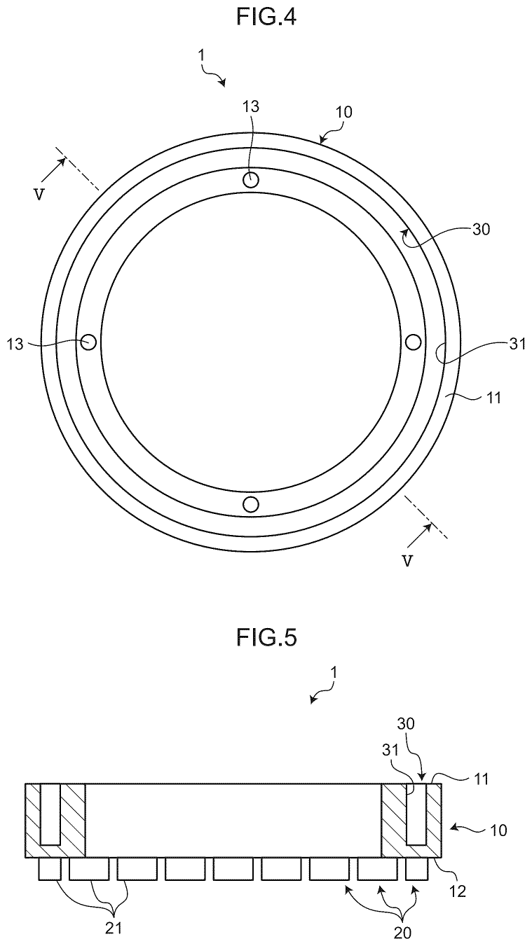

Next, the grinding wheel 1 will be described. FIG. 4 is a plan view illustrating the grinding wheel according to the first embodiment. FIG. 5 is a cross-sectional view taken along line V-V passing through an axial center in FIG. 4. The grinding wheel 1 illustrated in FIGS. 4 and 5 is used when grinding processing is performed on the back surface 205 side of the workpiece 200. In the first embodiment, the grinding wheel 1 grinds the entire back surface 205 of the workpiece 200 to thin the workpiece 200 to a predetermined thickness.

The grinding wheel 1 is mounted on the mount 124 of the spindle 121 and is used when grinding the back surface 205 side of the workpiece 200. As illustrated in FIGS. 4 and 5, the grinding wheel 1 includes an annular wheel base 10 mounted on the mount 124 provided at the lower end of the spindle 121 of the grinding unit, and a plurality of grinding abrasive products 20 (corresponding to grinding members).

The wheel base 10 is formed in an annular shape and has an annular first surface 11 and an annular second surface 12 on the side opposite to the first surface 11. The first surface 11 of the wheel base 10 is mounted on the mount 124 at the lower end of the spindle 121 that rotates in a predetermined rotation direction around the axis. When the wheel base 10 is mounted on the mount 124 at the lower end of the spindle 121, the wheel base is disposed coaxially with the spindle 121 and the mount 124. In the first embodiment, the wheel base 10 is mounted on the lower surface of the mount 124 by, for example, passing a bolt (not illustrated) through an attachment hole 13 that is open to the first surface 11 and is not open to the second surface 12.

In the first embodiment, the wheel base 10 is made of resin. The resin constituting the wheel base 10 is resin having hardness enough to restrict elastic deformation of the wheel base 10 before the grinding abrasive product 20 comes into contact with the back surface 205 of the workpiece 200 while the wheel base 10 is mounted on the mount 124. In addition, the resin constituting the wheel base 10 is resin having hardness that allows elastic deformation of the wheel base 10 when the wheel base 10 is mounted on the mount 124, and the grinding abrasive product 20 comes into contact with the back surface 205 of the workpiece 200 and is pressed against the back surface 205 to grind the back surface 205. In the first embodiment, the resin constituting the wheel base 10 is photocurable acrylic resin or epoxy resin, thermosetting epoxy resin, or the like.

The grinding abrasive product 20 is configured as one so-called segment abrasive product formed as one lump by mixing abrasives such as diamond or cubic boron nitride (CBN) with a bonding material (also referred to as a bond material) configured by metal, ceramic, resin, or the like. In the first embodiment, the grinding abrasive product 20 is formed to have a constant thickness and width over the entire length, and is curved in an arc shape having a curvature equivalent to that of the wheel base 10.

The grinding abrasive product 20 is disposed in an annular shape on the second surface 12 side of the wheel base 10. The plurality of grinding abrasive products 20 are arranged at equal intervals in a circumferential direction of the wheel base 10 and are fixed to the second surface 12 side of the wheel base 10. The grinding abrasive product 20 has a flat bottom surface 21 in contact with the back surface 205 of the workpiece 200 on the side opposite to the second surface 12 side. The bottom surface 21 is parallel to the back surface 205 of the workpiece 200 before the wheel base 10 is mounted on the mount 124 and comes into contact with the back surface 205 of the workpiece 200.

In the first embodiment, the grinding wheel 1 includes a movement controller 30. The movement controller 30 controls the grinding abrasive product 20 to be movable such that a contact area of the bottom surface 21 is changed in terms of the bottom surface 21 of the grinding abrasive product 20 with respect to the back surface 205 of the workpiece 200. In the first embodiment, the movement controller 30 is configured by forming a groove 31 recessed from the first surface 11 of the wheel base 10. In the first embodiment, the groove 31 constituting the movement controller 30 is formed in an annular shape coaxial with the first surface and is formed over the entire circumference of the wheel base 10.

In addition, the movement controller 30 is formed so as to at least partially overlap the grinding abrasive product 20 arranged on the second surface 12 side in plan view. In addition, in the first embodiment, the groove 31 constituting the movement controller 30 is disposed at a position where the grinding abrasive product 20 overlaps in a thickness direction of the wheel base 10.

### Method for Manufacturing Chip

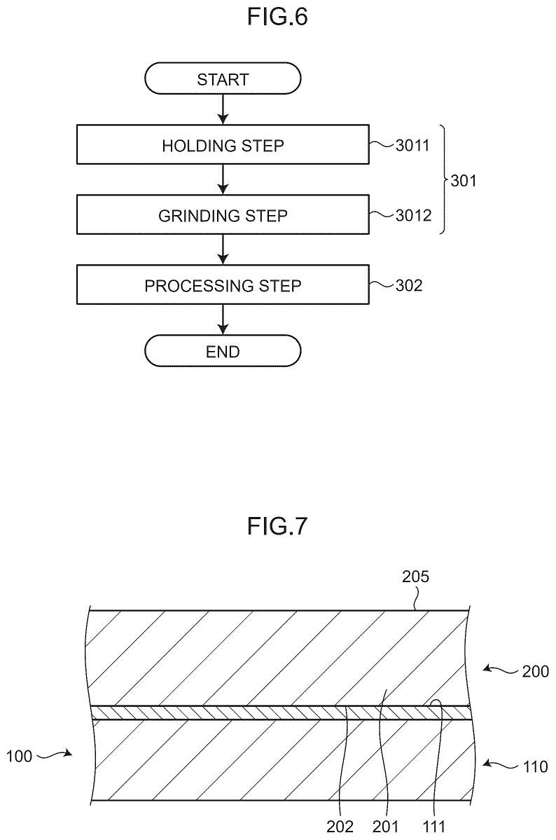

Next, a method for manufacturing a chip according to the first embodiment will be described. The method for manufacturing a chip according to the first embodiment is a method in which the workpiece 200 is ground and thinned using the grinding wheel 1 described above, and then the workpiece 200 is divided into individual chips 210 to manufacture chips. The chip 210 includes a portion of the substrate 201 and the device 204. FIG. 6 is a flowchart illustrating a flow of the method for manufacturing a chip according to the first embodiment. As illustrated in FIG. 6, the method for manufacturing a chip includes a thinning step 301 and a processing step 302.

### Thinning Step

The thinning step 301 is a step of grinding the workpiece 200 by holding the front surface 202 side of the workpiece 200 by the chuck table 110 and bringing the bottom surface 21 of the grinding abrasive product 20 into contact with the back surface 205 of the workpiece 200 while supplying liquid to the back surface 205 side of the workpiece 200. The thinning step 301 includes a holding step 3011 and a grinding step 3012, as illustrated in FIG. 6.

### Holding Step

FIG. 7 is an enlarged cross-sectional view illustrating a main part of the holding step in the method for manufacturing a chip illustrated in FIG. 6. The holding step 3011 is a step of holding the front surface 202 side of the workpiece 200 by the chuck table 110.

In the grinding device 100 having the above-described configuration, the front surface 202 side of the workpiece 200 before the grinding processing is placed on the holding surface 111 of the chuck table 110 at the loading and unloading position by the operator or the like, and the processing conditions input by the operator or the like are received by the control unit. The grinding device 100 starts the holding step 3011 when the control unit receives an instruction to start the processing operation input by the operator.

In the holding step 3011, the grinding device 100 drives the spindle motor 122 while the control unit supplies a grinding fluid, which is a liquid, to the grinding abrasive product 20 of the grinding wheel 1 to start rotation about the axis of the spindle 121 and the grinding wheel 1. In addition, in the holding step 3011, as illustrated in FIG. 7, in the grinding device 100, the control unit operates the suction source to cause the holding surface 111 of the chuck table 110 to suck and hold the front surface 202 side of the workpiece 200 to expose the back surface 205 of the workpiece 200 upward.

### Grinding Step

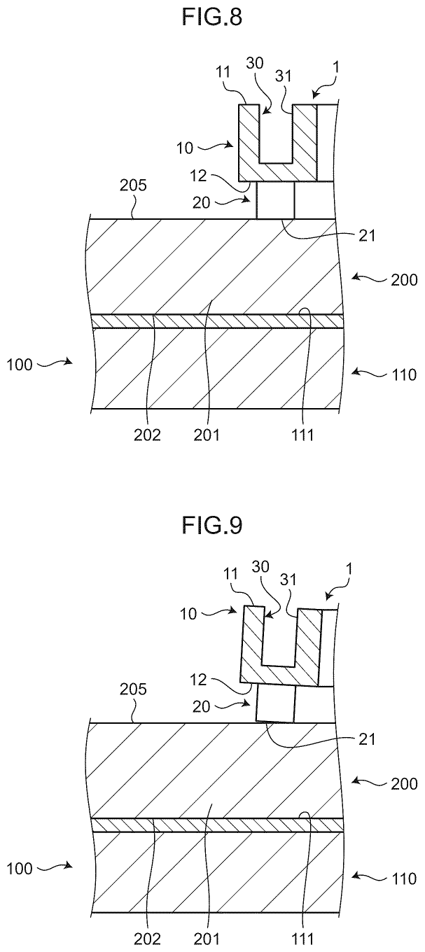

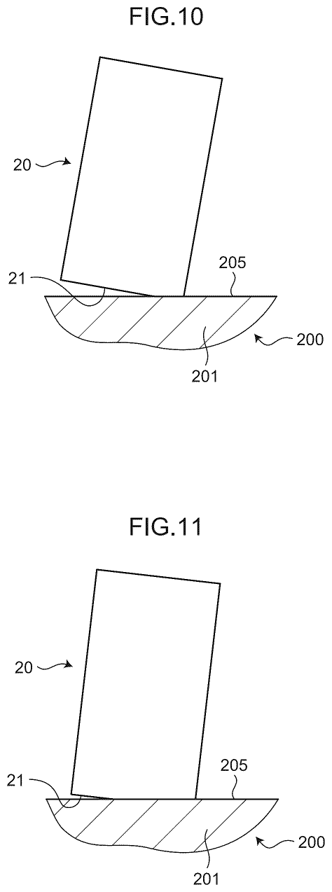

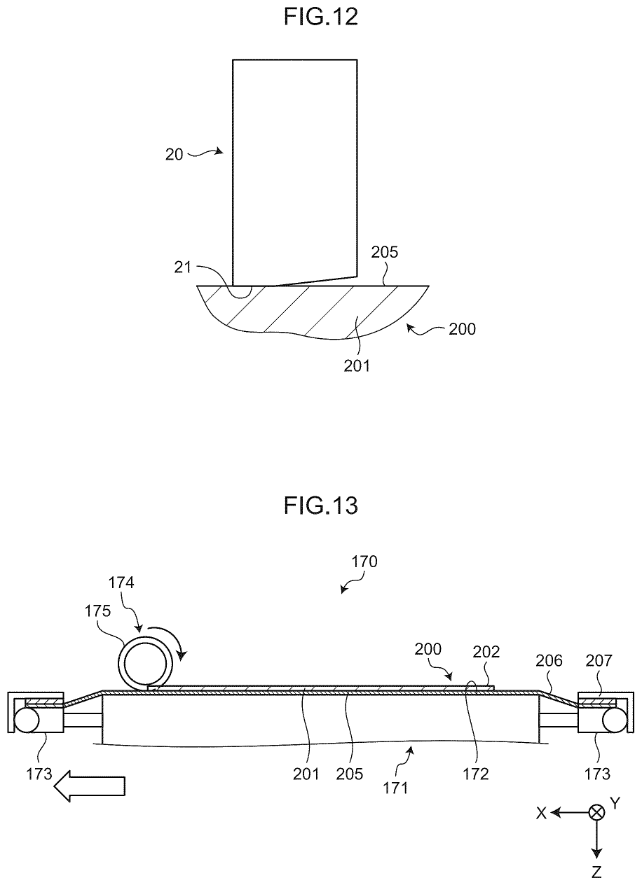

FIG. 8 is an enlarged cross-sectional view illustrating a state in which the bottom surface of the grinding abrasive product abuts on the back surface of the workpiece in the grinding step of the method for manufacturing a chip illustrated in FIG. 6. FIG. 9 is an enlarged cross-sectional view illustrating a state in which the grinding wheel is fed for grinding in the grinding step of the method for manufacturing a chip illustrated in FIG. 6. FIG. 10 is an enlarged cross-sectional view illustrating the grinding abrasive product illustrated in FIG. 9. FIG. 11 is an enlarged cross-sectional view illustrating an abrasive product member in a state in which the grinding abrasive product illustrated in FIG. 10 starts grinding the workpiece. FIG. 12 is an enlarged cross-sectional view illustrating the abrasive product member in a state in which the grinding abrasive product illustrated in FIG. 11 is grinding the workpiece.

In the grinding step 3012, the grinding device 100 causes the control unit to control the processing feed unit 130 to move the chuck table 110 sucking and holding the workpiece 200 to the processing position. In the grinding step 3012, the control unit rotates the chuck table 110 about the axis, and the grinding device 100 controls the grinding feed unit 140 to lower the grinding wheel 1 rotated about the axis. Then, as illustrated in FIG. 8, the bottom surface 21 of the grinding abrasive product 20 comes into contact with the back surface 205 of the workpiece 200.

In the grinding step 3012, the grinding device 100 controls the grinding feed unit 140 to further lower the grinding wheel 1. Then, until the grinding abrasive product 20 performs the grinding processing on the back surface 205 of the workpiece 200, the grinding abrasive product 20 slides on the back surface 205 of the workpiece 200, and a grinding load exerted by the grinding abrasive product 20 on the workpiece 200 increases. When the grinding load increases, in the first embodiment, the wheel base 10 is elastically deformed by the movement controller 30 such that the bottom surface 21 of the grinding abrasive product 20 faces an outer peripheral direction of the grinding wheel 1 as illustrated in FIGS. 9 and 10. Specifically, in the first embodiment, the wheel base 10 is elastically deformed such that a width of an opening on the first surface 11 side of the movement controller 30 is narrowed.

As described above, in the first embodiment, in the grinding step 3012, when a certain grinding load or more is applied to the back surface 205 of the workpiece 200, the grinding abrasive product 20 is moved by the movement controller 30 such that the contact area of the bottom surface 21 of the grinding abrasive product 20 becomes small. Then, in the first embodiment, in the grinding step 3012, a surface pressure (pressure that is a load per unit area) of the grinding abrasive product 20 at the contact portion increases to promote self-blade generation, the grinding abrasive product 20 starts grinding the back surface 205 of the workpiece 200 with the exposed abrasives, and the grinding load gradually decreases.

In the first embodiment, in the grinding step 3012, as the grinding load gradually decreases, the movement controller 30 attempts to return the wheel base 10 to an initial state such that the bottom surface 21 of the grinding abrasive product 20 is directed in an inner circumferential direction of the grinding wheel 1 as illustrated in FIG. 11. Thus, in the first embodiment, in the grinding step 3012, the grinding abrasive product 20 is moved by the movement controller 30 such that the contact area of the bottom surface 21 of the grinding abrasive product 20 is increased. In the first embodiment, in the grinding step 3012, as illustrated in FIG. 12, the entire bottom surface 21 of the grinding abrasive product 20 abuts on the back surface 205 of the workpiece 200 to grind the back surface 205 of the workpiece 200.

In the first embodiment, in the grinding step 3012, in the processing operation, when the grinding device 100 thins the workpiece 200 to a predetermined thickness with the grinding abrasive product 20, the control unit controls the grinding feed unit 140 to raise the grinding wheel 1. In the first embodiment, in the grinding step 3012, the grinding device 100 stops the rotation about the axis of the chuck table 110 via the control unit, then controls the processing feed unit 130 to convey the chuck table 110 that sucks and holds the workpiece 200 subjected to the grinding processing to the loading and unloading position. In the first embodiment, in the grinding step 3012, the grinding device 100 stops suction holding of the chuck table 110 at the loading and unloading position, and the workpiece 200 subjected to the grinding processing is accommodated in the cassette 104 by the loading and unloading unit 150. In the first embodiment, the grinding device 100 performs the thinning step 301 one by one on the workpieces 200 in the cassette 104. In the first embodiment, when the thinning step 301 is performed on all of the workpieces 200 in the cassette 104, the grinding device 100 ends the processing operation.

In this way, in the grinding step 3012 of the thinning step 301, the grinding wheel 1 is controlled by the movement controller 30 to grind such that the contact area of the bottom surface 21 is changed in terms of the bottom surface 21 of the grinding abrasive product 20 with respect to the back surface 205 of the workpiece 200. In addition, the holding step 3011 and the grinding step 3012 described above constitute a workpiece grinding method for grinding the workpiece 200 using the grinding wheel 1 having the above-described configuration.

### Processing Step

FIG. 13 is a side view schematically illustrating the processing step of the method for manufacturing a chip illustrated in FIG. 6 in a partial cross section. The processing step 302 is a step of dividing the workpiece 200 into individual chips 210.

In the first embodiment, in the processing step 302, a tape 206 formed in a disk shape having a diameter larger than that of the workpiece 200 is bonded to the back surface 205 of the workpiece 200, and an annular frame 207 having an inner diameter larger than that of the workpiece 200 is bonded to an outer edge portion of the tape 206, so that the workpiece 200 is supported by the frame 207. In the first embodiment, in the processing step 302, a cutting device 170 illustrated in FIG. 13 sucks and holds the workpiece 200 on a holding surface 172 of a holding table 171, and clamps the frame 207 with a clamp unit 173.

In the first embodiment, in the processing step 302, the cutting device 170 rotates a spindle of a cutting unit 174 and starts supply of cutting water to a cutting blade 175. In the first embodiment, in the processing step 302, the cutting device 170 moves the holding table 171 toward a lower side of the cutting unit 174, images the workpiece 200 sucked and held on the holding table 171 by an imaging unit, and performs alignment for aligning the cutting blade 175 and the workpiece 200 based on an image or the like obtained by imaging.

In the first embodiment, in the processing step 302, as illustrated in FIG. 13, the cutting device 170 cuts the workpiece 200 along a division-planned line 203 by cutting the division-planned line 203 with the cutting blade 175 until the cutting blade reaches the tape 206 while moving the cutting blade 175 and the workpiece 200 relative to each other. In the first embodiment, in the processing step 302, the cutting device 170 cuts all of the division-planned lines 203 of the workpiece 200 to divide the workpiece 200 into the chips 210. In the present disclosure, in the processing step 302, the workpiece 200 may be subjected to laser ablation processing to be divided into individual chips 210.

As described above, the grinding wheel 1 and the method for manufacturing a chip according to the first embodiment include the movement controller 30 that movably controls the grinding abrasive product 20 such that the contact area of the bottom surface 21 is changed in terms of the bottom surface 21 of the grinding abrasive product 20 with respect to the back surface 205 of the workpiece 200 and the bottom surface 21 of the grinding abrasive product 20 with respect to the back surface 205 of the workpiece 200. According to this, in the grinding wheel 1 and the method for manufacturing a chip according to the first embodiment, when a certain grinding load or more is applied to the back surface 205 of the workpiece 200, the grinding abrasive product 20 moves such that the contact area of the bottom surface 21 of the grinding abrasive product 20 becomes small.

Then, in the grinding wheel 1 and the method for manufacturing a chip according to the first embodiment, the surface pressure of the grinding abrasive product 20 at the contact portion increases to promote self-blade generation, and grinding proceeds with the exposed abrasives. Thereafter, in the grinding wheel 1 and the method for manufacturing a chip according to the first embodiment, the grinding abrasive product 20 moves such that the contact area of the bottom surface 21 of the grinding abrasive product 20 increases as the grinding load gradually decreases. Therefore, the grinding wheel 1 and the method for manufacturing a chip according to the first embodiment can reduce an increase in the grinding load on the workpiece 200 in the grinding wheel 1 for grinding the workpiece 200.

As a result, the grinding wheel 1 and the method for manufacturing a chip according to the first embodiment have an effect of reducing the grinding load of the grinding abrasive product 20 on the workpiece 200.

### Second Embodiment

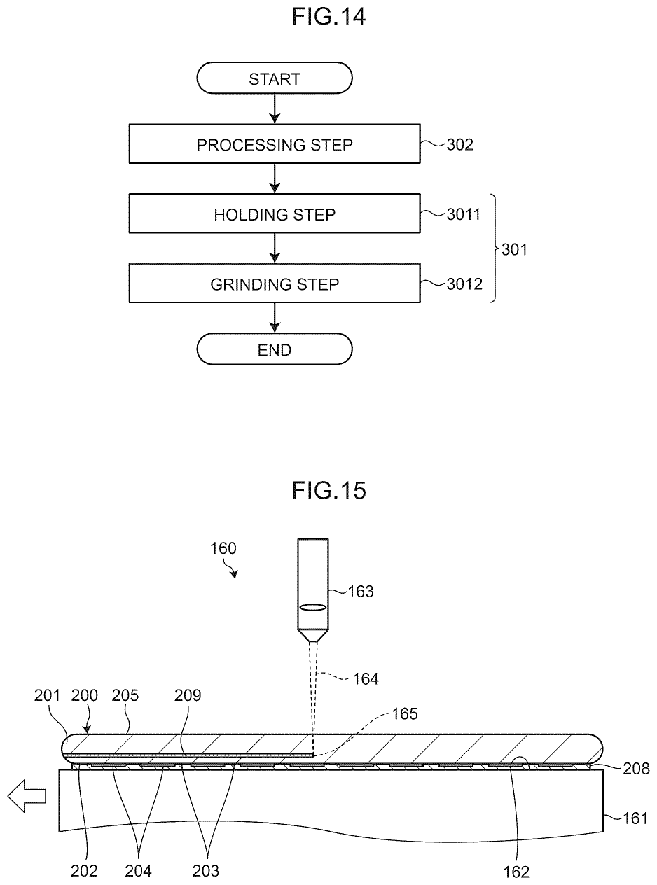

A method for manufacturing a chip according to a second embodiment will be described with reference to the drawings. FIG. 14 is a flowchart illustrating a flow of the method for manufacturing a chip according to the second embodiment. FIG. 15 is a side view schematically illustrating a processing step of the method for manufacturing a chip illustrated in FIG. 14 in a partial cross section. In FIGS. 14 and 15, the same parts as those in the first embodiment are denoted by the same reference numerals, and descriptions thereof are omitted.

As illustrated in FIG. 14, the method for manufacturing a chip according to the second embodiment performs the thinning step 301 after performing the processing step 302. In the second embodiment, the processing step 302 is a step of forming a division starting point 209 in the workpiece 200.

In the second embodiment, in the processing step 302, a tape 208 formed in a disk shape having the same diameter as the workpiece 200 is bonded to the front surface 202 of the workpiece 200. In the second embodiment, in the processing step 302, a laser processing device 160 illustrated in FIG. 15 sucks and holds the front surface 202 side of the workpiece 200 on a holding surface 162 of a holding table 161.

In the second embodiment, in the processing step 302, the laser processing device 160 moves the holding table 161 toward a lower side of a laser beam irradiation unit 163, images the workpiece 200 sucked and held on the holding table 171 by the imaging unit, and performs alignment for aligning the laser beam irradiation unit 163 and the workpiece 200 based on an image or the like obtained by imaging. In the second embodiment, in the processing step 302, as illustrated in FIG. 15, the laser processing device 160 sets a focal point 165 within the workpiece 200 and irradiates a laser beam 164 from the laser beam irradiation unit 163 onto the division-planned line 203 of the workpiece 200 while moving the laser beam irradiation unit 163 and the workpiece 200 relative to each other along the division-planned line 203.

In the second embodiment, in the processing step 302, the laser processing device 160 forms a modified layer, which is a division starting point 209, inside all the division-planned lines 203 of the workpiece 200. The modified layer means a region in which density, refractive index, mechanical strength, and other physical characteristics are different from those of surrounding regions, and examples of the modified layer include a melted region, a crack region, a dielectric breakdown region, a refractive index change region, and a region in which these regions are mixed. In addition, the modified layer has lower mechanical strength and the like than other portions of the workpiece 200.

In the second embodiment, in the grinding step 3012, the grinding device 100 grinds the back surface 205 of the workpiece 200 to divide the workpiece 200 into individual chips 210 starting from the division starting point 209.

The grinding wheel 1 and the method for manufacturing a chip according to the second embodiment include the movement controller 30 that movably controls the grinding abrasive product 20 such that the contact area of the bottom surface 21 is changed in terms of the bottom surface 21 of the grinding abrasive product 20 with respect to the back surface 205 of the workpiece 200. Therefore, the grinding wheel 1 and the method for manufacturing a chip according to the second embodiment have an effect of reducing the grinding load of the grinding abrasive product 20 on the workpiece 200, as in the first embodiment.

In the present disclosure, a processing groove along the division-planned line 203 may be formed as the division starting point 209.

### Modification

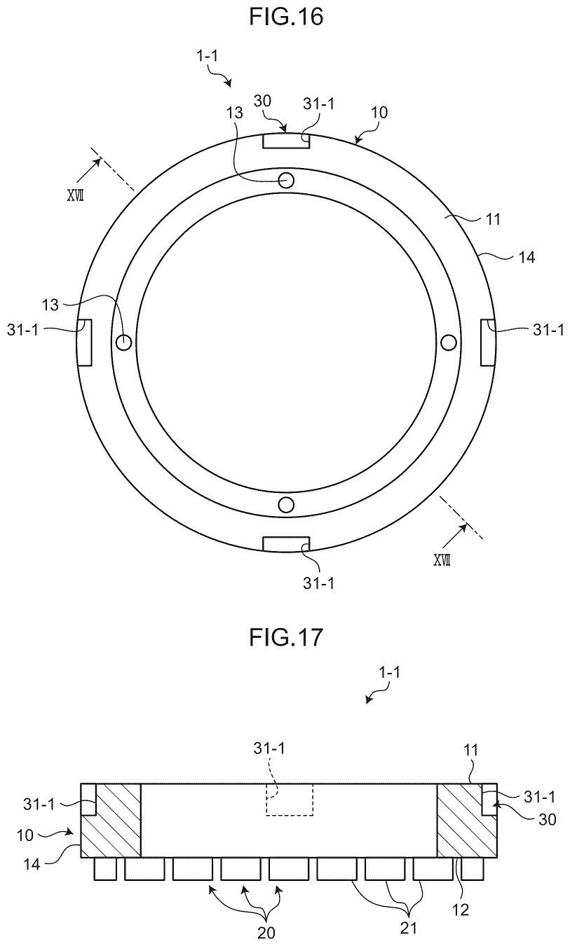

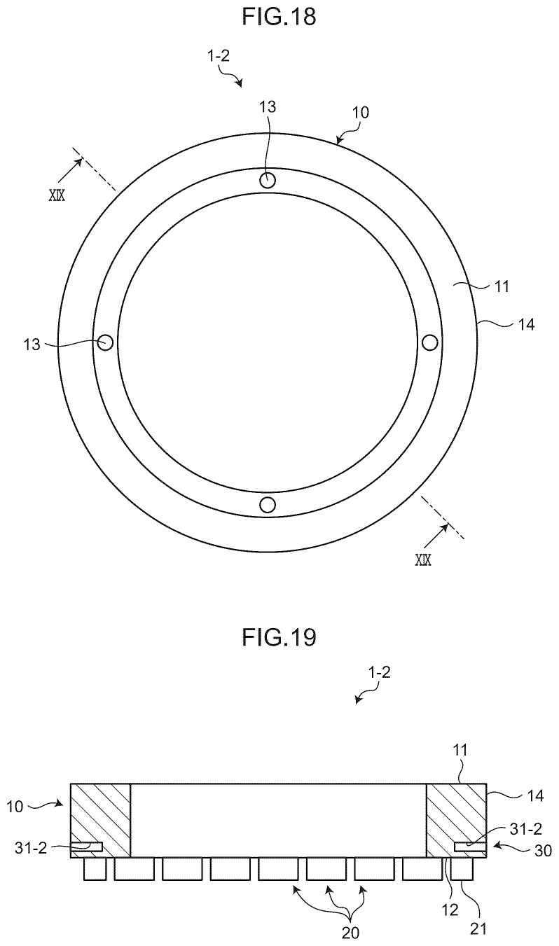

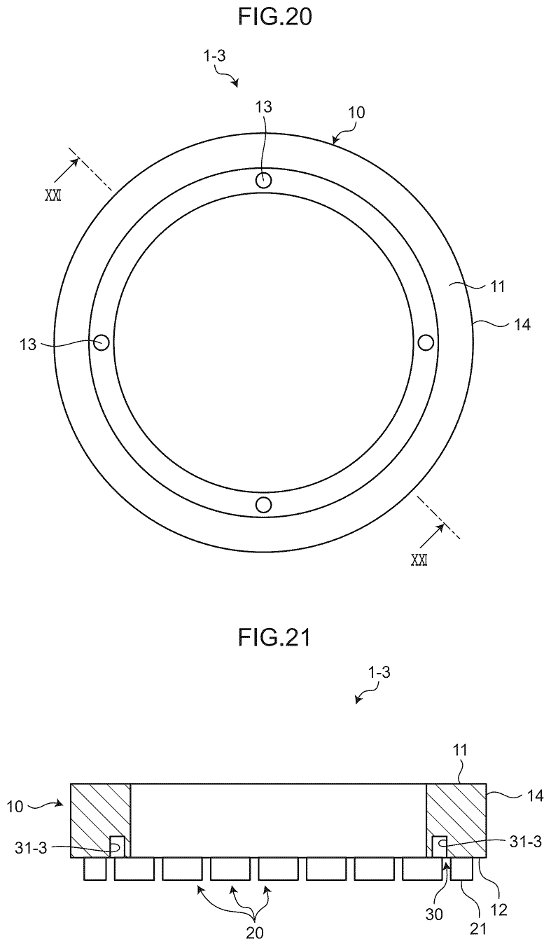

A grinding wheel according to modifications of the present disclosure will be described with reference to the drawings. FIG. 16 is a plan view illustrating a grinding wheel according to a first modification. FIG. 17 is a cross-sectional view taken along line XVII-XVII passing through an axial center in FIG. 16. FIG. 18 is a plan view illustrating a grinding wheel according to a second modification. FIG. 19 is a cross-sectional view taken along line XIX-XIX passing through an axial center in FIG. 18. FIG. 20 is a plan view illustrating a grinding wheel according to a third modification. FIG. 21 is a cross-sectional view taken along line XXI-XXI passing through an axial center in FIG. 20. In FIGS. 16, 17, 18, 19, 20, and 21, the same parts as those in the first embodiment are denoted by the same reference numerals, and descriptions thereof are omitted.

As illustrated in FIGS. 16 and 17, in a grinding wheel 1-1 according to the first modification, grooves 31-1 constituting the movement controller 30 are formed over the first surface 11 and an outer peripheral surface 14 of the wheel base 10, and a plurality of the grooves are provided at intervals in the circumferential direction of the wheel base 10.

In a grinding wheel 1-2 illustrated in FIG. 18 according to the second modification, as illustrated in FIG. 19, grooves 31-2 constituting the movement controller 30 are provided near the second surface 12 in the thickness direction of the wheel base 10 and formed on the outer peripheral surface 14, and a plurality of the grooves are provided at intervals in the circumferential direction of the wheel base 10.

In a grinding wheel 1-3 illustrated in FIG. 20 according to the third modification, as illustrated in FIG. 21, grooves 31-3 constituting the movement controller 30 are provided on the inner peripheral side than the grinding abrasive product 20 of the wheel base 10 and formed on the second surface 12, and a plurality of the grooves are provided at intervals in the circumferential direction of the wheel base 10.

The grinding wheels 1-1, 1-2, and 1-3 according to the first, second, and third modifications include the movement controller 30 that movably controls the grinding abrasive product 20 such that the contact area of the bottom surface 21 is changed in terms of the bottom surface 21 of the grinding abrasive product 20 with respect to the back surface 205 of the workpiece 200, and thus, an effect that the grinding load of the grinding abrasive product 20 with respect to the workpiece 200 can be reduced is obtained similarly to the first embodiment.

Next, the inventors of the present disclosure checked the effect of the grinding wheel 1 according to the first embodiment. Results are illustrated in Table 1 below.

TABLE 1

| | Grinding Load | Wear Amount |
|---|---|---|
| Inventive Product | 79% | 94% |
| Comparative Example | 100% | 100% |

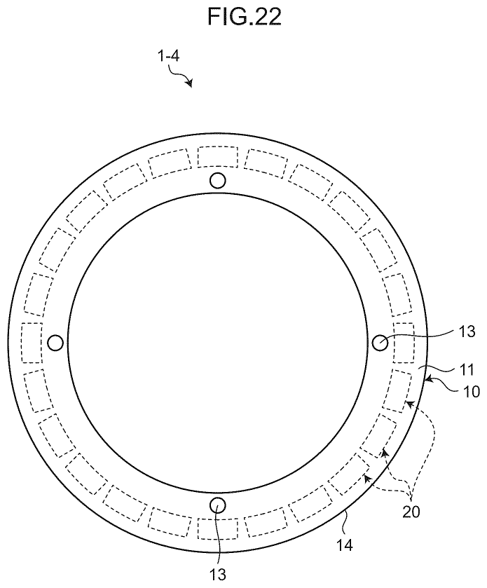

The results in Table 1 were obtained by measuring a grinding load and a wear amount of the grinding abrasive product 20 when grinding the workpiece 200 having the substrate 201 made of SiC and an outer diameter of 6 inches using the grinding wheel 1 according to the first embodiment as the inventive product. The results in Table 1 were obtained by measuring the grinding load and the wear amount of the grinding abrasive product 20 when grinding the workpiece 200 having the substrate 201 made of SiC and an outer diameter of 6 inches using a grinding wheel 1-4 of a comparative example illustrated in FIG. 22.

FIG. 22 is a plan view illustrating the grinding wheel according to the comparative example. In the grinding wheel 1-4 of the comparative example illustrated in FIG. 22, the same parts as those of the first embodiment are denoted by the same reference numerals, and the descriptions thereof will be omitted. The grinding wheel 1-4 of the comparative example illustrated in FIG. 22 has the same configuration as the grinding wheel 1 according to the first embodiment except that the grooves 31 constituting the movement controller 30 are removed and the wheel base 10 is made of an aluminum alloy.

Table 1 illustrates the grinding load of the grinding wheel 1-4 and the wear amount of the grinding abrasive product 20 of the comparative example at 100%. According to Table 1, in the inventive product, the grinding load was 79% of that in the comparative example, and the wear amount of the grinding abrasive product 20 was 94% of that in the comparative example.

As described above, according to Table 1, it has become clear that the grinding wheel 1 can reduce the grinding load and the wear amount of the grinding abrasive product 20 by including the movement controller 30.

According to the present disclosure, it is possible to reduce a grinding load on a workpiece.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

For example, in the present disclosure, the movement controller 30 may elastically deform the wheel base 10 in a direction in which the bottom surface 21 of the grinding abrasive product 20 moves toward an inner periphery of the grinding wheel 1. In addition, in the present disclosure, the movement controller 30 of the grinding wheel 1 may be a hollow cavity provided in the wheel base 10, or may be configured by the grooves 31, 31-1, 31-2, and 31-3 and the hollow cavity.

In addition, in the present disclosure, the movement controller 30 may be formed such that the thickness of the wheel base 10 gradually decreases toward the outer periphery as the outer periphery of the wheel base 10 is subjected to edge trimming.

What is claimed is:

1. A grinding wheel used when grinding a back surface side of a plate-shaped workpiece having a front surface and a back surface on the side opposite to the front surface, the grinding wheel comprising:
a wheel base having a first surface and a second surface on the side opposite to the first surface, the first surface side being mounted on a spindle rotating in a predetermined rotation direction;
a plurality of abrasive product members disposed on the second surface side of the wheel base and having a bottom surface in contact with the back surface of the workpiece; and
a movement controller configured to movably control the abrasive product member such that the contact area of the bottom surface is changed in terms of the bottom surface of the abrasive product member with respect to the back surface of the workpiece.

2. The grinding wheel according to claim 1, wherein the movement controller is formed to at least partially overlap the abrasive product member arranged on the second surface side in plan view.

3. The grinding wheel according to claim 1, wherein the movement controller is configured by forming a groove and/or a hollow cavity in the wheel base.

4. A grinding method of a workpiece that grinds the workpiece using the grinding wheel according to claim 1, the method comprising:
holding the front surface side of the workpiece with a chuck table; and
grinding the workpiece by bringing the bottom surface of the abrasive product member into contact with the back surface of the workpiece while supplying liquid to the back surface side of the workpiece, wherein
the grinding includes, by the grinding wheel, grinding by controlling the bottom surface of the abrasive product member such that the contact area of the bottom surface is changed with respect to the back surface of the workpiece.

5. A method for manufacturing a chip by dividing a workpiece into individual chips using the grinding wheel according to claim 1, the method comprising:
holding the front surface side of the workpiece with a chuck table, and grinding the workpiece to thin the workpiece by bringing the bottom surface of the abrasive product member into contact with the back surface of the workpiece while supplying liquid to the back surface side of the workpiece; and
dividing the workpiece into individual chips or forming a division starting point on the workpiece to process the workpiece, wherein
the grinding to thin the workpiece includes, by the grinding wheel, grinding by controlling the bottom surface of the abrasive product member such that the contact area of the bottom surface is changed with respect to the back surface of the workpiece.
